(19) United States
(12) Patent Application Publication
(10) Pub. No.: US 2024/0310441 A1
(43) Pub. Date: Sep. 19, 2024

(54) SYSTEMS, APPARATUSES, METHODS, AND COMPUTER PROGRAM PRODUCTS FOR GENERATING A LIFE CURVE ASSOCIATED WITH A SWITCH TYPE

(71) Applicant: HONEYWELL INTERNATIONAL INC., Charlotte, NC (US)

(72) Inventor: Ravikumar MANGALA, Charlotte, NC (US)

(21) Appl. No.: 18/587,097

(22) Filed: Feb. 26, 2024

(30) Foreign Application Priority Data
Mar. 13, 2023 (IN) 202311016600

(51) Int. Cl. G01R 31/327

(52) U.S. Cl. CPC G01R 31/3277

(57) ABSTRACT

An example system for generating a life curve associated with a switch type and an associated method. In some embodiments, the method may include generating a switch failure dataset associated with the switch type. In some embodiments, the switch failure dataset comprises mean failure data associated with the switch type indicating a predicted number of times a switch of the switch type may be cycled before failing. In some embodiments, the method may include determining a best fit distribution for the switch type based at least on the switch failure dataset using one or more regression models. In some embodiments, the method may include generating the life curve for the switch type based at least on the best fit distribution.

### CROSS-REFERENCE TO RELATED APPLICATIONS

This application claims priority pursuant to 35 U.S.C. 119(a) to Indian Application No. 202311016600, filed Mar. 13, 2023, which application is incorporated herein by reference in its entirety.

### TECHNOLOGICAL FIELD

Embodiments of the present disclosure relate generally to generating a life curve associated with a switch type.

### BACKGROUND

Applicant has identified many technical challenges and difficulties associated with generating a life curve associated with a switch type. Through applied effort, ingenuity, and innovation, Applicant has solved problems related to generating a life curve associated with a switch type by developing solutions embodied in the present disclosure, which are described in detail below.

### BRIEF SUMMARY

Various embodiments described herein relate to generating a life curve associated with a switch type.

In accordance with one aspect of the disclosure, a method of generating a life curve associated with a switch type is provided.

In some embodiments, the method may include generating a switch failure dataset associated with the switch type. In some embodiments, the switch failure dataset comprises mean failure data associated with the switch type indicating a predicted number of times a switch of the switch type may be cycled before failing. In some embodiments, the method may include determining a best fit distribution for the switch type based at least on the switch failure dataset using one or more regression models. In some embodiments, the method may include generating the life curve for the switch type based at least on the best fit distribution.

In some embodiments, generating the switch failure dataset may include causing a first plurality of switches associated with the switch type to perform one or more switch cycles. In some embodiments, in each switch cycle a first current of a plurality of currents is applied to each switch of the first plurality of switches. In some embodiments, generating the switch failure dataset may include determining that each of the first plurality of switches has failed. In some embodiments, generating the switch failure dataset may include determining a number of switch cycles each of the first plurality of switches performed before failing. In some embodiments, generating the switch failure dataset may include generating first failure data associated with the first plurality of switches based at least on the number of switch cycles each of the first plurality of switches performed before failing. In some embodiments, generating the switch failure dataset may include iteratively generating other failure data based at least on applying other currents of the plurality of currents to other pluralities of switches associated with the switch type. In some embodiments, generating the switch failure dataset may include generating preliminary mean failure data associated with the switch type based at least on the first failure data and the other failure data. In some embodiments, generating the switch failure dataset may include generating the mean failure data by adjusting the preliminary mean failure data by a confidence level.

In some embodiments, each of the one or more switch cycles comprises an on time period and an off time period.

In some embodiments, the first current is applied to each switch of the first plurality of switches during the on time period.

In some embodiments, the first current is between one ampere and twenty amperes.

In some embodiments, the on period is less than two seconds.

In some embodiments, a switch of the first plurality of switches has failed when the switch is unable to be cycled between the on time period and the off time period.

In some embodiments, the best fit distribution is selected from a plurality of best fit distributions.

In some embodiments, the plurality of best fit distributions comprise an exponential distribution, a logarithmic distribution, a linear distribution, and a power distribution.

In some embodiments, the method may include causing the life curve for the switch type to be automatically displayed on a user interface based at least on the best fit distribution.

In accordance with another aspect of the disclosure, a system for generating a life curve is provided. In some embodiments, the system may include a plurality of switches associated with the switch type. In some embodiments, the system may include a switch testing apparatus comprising at least one processor and at least one non-transitory memory having one or more programs stored thereon that include instructions that, when executed by the at least one processor, causes the apparatus to generate a switch failure dataset associated with the switch type. In some embodiments, the switch failure dataset comprises mean failure data associated with the switch type indicating a predicted number of times a switch of the switch type may be cycled before failing. In some embodiments, the switch testing apparatus is caused to determine a best fit distribution for the switch type based at least on the switch failure dataset using one or more regression models. In some embodiments, the switch testing apparatus is caused to generate the life curve for the switch type based at least on the best fit distribution.

In some embodiments, the switch testing apparatus is caused to generate the switch failure dataset by causing a first plurality of switches associated with the switch type to perform one or more switch cycles. In some embodiments, in each switch cycle a first current of a plurality of currents is applied to each switch of the first plurality of switches. In some embodiments, the switch testing apparatus is caused to generate the switch failure dataset by determining that each of the first plurality of switches has failed. In some embodiments, the switch testing apparatus is caused to generate the switch failure dataset by determining a number of switch cycles each of the first plurality of switches performed before failing. In some embodiments, the switch testing apparatus is caused to generate the switch failure dataset by generating first failure data associated with the first plurality of switches based at least on the number of switch cycles each of the first plurality of switches performed before failing. In some embodiments, the switch testing apparatus is caused to generate the switch failure dataset by iteratively generating other failure data based at least on applying other currents of the plurality of currents to other pluralities of switches associated with the switch type. In some embodiments, the switch testing apparatus is caused to generate the switch failure dataset by generating preliminary mean failure data associated with the switch type based at least on the first failure data and the other failure data. In some embodiments, the switch testing apparatus is caused to generate the switch failure dataset by generating the mean failure data by adjusting the preliminary mean failure data by a confidence level.

In some embodiments, each of the one or more switch cycles comprises an on time period and an off time period.

In some embodiments, the first current is applied to each switch of the first plurality of switches during the on time period.

In some embodiments, the first current is between one ampere and twenty amperes.

In some embodiments, the on period is less than two seconds.

In some embodiments, a switch of the first plurality of switches has failed when the switch is unable to be cycled between the on time period and the off time period.

In some embodiments, the best fit distribution is selected from a plurality of best fit distributions.

In some embodiments, the plurality of best fit distributions comprise an exponential distribution, a logarithmic distribution, a linear distribution, and a power distribution.

In some embodiments, the switch testing apparatus is caused to automatically display the life curve for the switch type on a user interface based at least on the best fit distribution.

In accordance with another aspect of the disclosure, at least one non-transitory computer-readable storage medium for generating a life curve associated with a switch type, the at least one non-transitory computer-readable storage medium having computer-executable program code portions stored therein, the computer-executable program code portions comprising program code instructions is provided. In some embodiments, the program code instructions are configured to generate a switch failure dataset associated with the switch type. In some embodiments, the switch failure dataset comprises mean failure data associated with the switch type indicating a predicted number of times a switch of the switch type may be cycled before failing. In some embodiments, the program code instructions are configured to determine a best fit distribution for the switch type based at least on the switch failure dataset using one or more regression models. In some embodiments, the program code instructions are configured to generate the life curve for the switch type based at least on the best fit distribution.

In some embodiments, generating the switch failure dataset may include causing a first plurality of switches associated with the switch type to perform one or more switch cycles. In some embodiments, in each switch cycle a first current of a plurality of currents is applied to each switch of the first plurality of switches. In some embodiments, generating the switch failure dataset may include determining that each of the first plurality of switches has failed. In some embodiments, generating the switch failure dataset may include determining a number of switch cycles each of the first plurality of switches performed before failing. In some embodiments, generating the switch failure dataset may include generating first failure data associated with the first plurality of switches based at least on the number of switch cycles each of the first plurality of switches performed before failing. In some embodiments, generating the switch failure dataset may include iteratively generating other failure data based at least on applying other currents of the plurality of currents to other pluralities of switches associated with the switch type. In some embodiments, generating the switch failure dataset may include generating preliminary mean failure data associated with the switch type based at least on the first failure data and the other failure data. In some embodiments, generating the switch failure dataset may include generating the mean failure data by adjusting the preliminary mean failure data by a confidence level.

In some embodiments, each of the one or more switch cycles comprises an on time period and an off time period.

In some embodiments, the first current is applied to each switch of the first plurality of switches during the on time period.

In some embodiments, the first current is between one ampere and twenty amperes.

In some embodiments, the on period is less than two seconds.

In some embodiments, a switch of the first plurality of switches has failed when the switch is unable to be cycled between the on time period and the off time period.

In some embodiments, the best fit distribution is selected from a plurality of best fit distributions.

In some embodiments, the plurality of best fit distributions comprise an exponential distribution, a logarithmic distribution, a linear distribution, and a power distribution.

In some embodiments, the program code instructions are configured to cause the life curve for the switch type to be automatically displayed on a user interface based at least on the best fit distribution.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates a schematic view of an example system for generating a life curve in accordance with one or more embodiments of the present disclosure;

FIG. 2 illustrates an example first failure data interface in accordance with one or more embodiments of the present disclosure;

FIG. 3 illustrates an example first other failure data interface in accordance with one or more embodiments of the present disclosure;

FIG. 4 illustrates an example second other failure data interface in accordance with one or more embodiments of the present disclosure;

FIG. 5 illustrates an example third other failure data interface in accordance with one or more embodiments of the present disclosure;

FIG. 6 illustrates an example first mean failure data interface in accordance with one or more embodiments of the present disclosure;

FIG. 7 illustrates an example second mean failure data interface in accordance with one or more embodiments of the present disclosure;

FIG. 8 illustrates an example life curve interface in accordance with one or more embodiments of the present disclosure;

FIG. 9 illustrates a flowchart of an example method of generating a life curve in accordance with one or more embodiments of the present disclosure; and

FIG. 10 illustrates a block diagram of an example computer processing device in accordance with one or more embodiments of the present disclosure.

### DETAILED DESCRIPTION

Example embodiments will be described more fully hereinafter with reference to the accompanying drawings, in which some, but not all embodiments of disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

### Overview

Example embodiments disclosed herein address technical problems associated with generating a life curve associated with a switch type. As would be understood by one skilled in the field to which this disclosure pertains, there are numerous example scenarios in which a user may desire to generate a life curve associated with a switch type.

In many applications, it is often necessary to know how many times a switch of a particular switch type may be cycled (e.g., used) before the switch fails (e.g., the expected lifetime of the switch). For example, in many industrial applications it may be necessary to know how many times a switch of a particular switch type may be cycled before the switch fails so that the switch can be replaced before it fails (e.g., to ensure that failure of the switch does not cause injury to individuals or equipment).

Example solutions for knowing how many times a switch of a switch type may be cycled before the switch fails include, for example, estimating a number of times that the switch of a switch type may be cycled based on the maximum operating current for the switch type. However, switches may regularly operate at a variety of currents other the maximum operating current. As a result, estimating the number of times that the switch of a switch type may be cycled based on the maximum operating current may lead to the estimated number of times that the switch of a switch type may be cycled being inaccurate. Thus, causing the switch to either be replaced too early and/or the switch not being replaced before it fails.

Thus, to address these and/or other issues related to knowing how many times a switch of a switch type before the switch fails, example systems, apparatuses, and/or methods for generating a live curve associated with a switch type are disclosed herein. For example, an embodiment in this disclosure, described in greater detail below, includes a system for generating a life curve associated with a switch type having a plurality of switches associated with the switch type and a switch testing apparatus. In some embodiments, the switch testing apparatus may be configured to generate a switch failure dataset associated with the switch type. In some embodiments, the switch failure dataset comprises mean failure data associated with the switch type indicating a predicted number of times a switch of the switch type may be cycled before failing. In some embodiments, the switch testing apparatus may be configured to determine a best fit distribution for the switch type based at least on the switch failure dataset using one or more regression models. In some embodiments, the switch testing apparatus may be configured to generate the life curve for the switch type based at least on the best fit distribution. Thus, the system enables for accurate prediction of how many times a switch may be cycled before it fails (e.g., based on the life curve) enabling for replacement of switches of the switch type at the appropriate time.

### Example Systems and Apparatuses

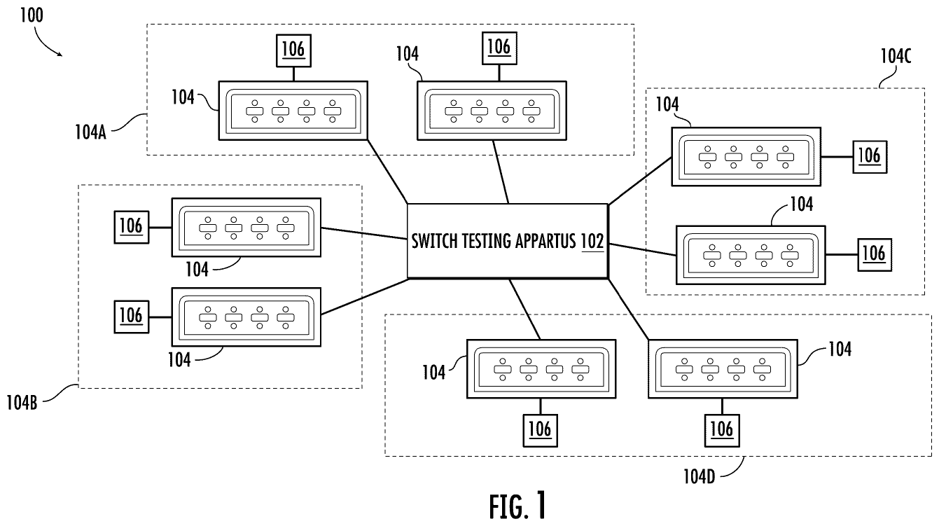

With reference to FIG. 1, a system for generating a life curve associated with a switch type 100 is illustrated. In some embodiments, the system for generating a life curve associated with a switch type 100 may include a plurality of switches 104. In some embodiments, each switch of the plurality of switches 104 may include a spring component and/or a static component. In some embodiments, each switch in the plurality of switches 104 may be associated with a switch type. In some embodiments, the switch type may be a basic switch type. For example, the switch type may be subminiature basic switch type, a miniature basic switch type, a large basic switch type, and/or the like. In some embodiments, the switch type may be a limit switch type. For example, the switch type may be a general purpose limit switch type, a door interlock limit switch type, a heavy duty limit switch type, and/or the like. In some embodiments, the plurality of switches 104 may include one or more subsets of plurality of switches. For example, the plurality of switches 104 may include a first plurality of switches 104A, a second plurality of switches 104B, a third plurality of switches 104C, and a fourth plurality of switches 104D.

Although illustrated in FIG. 1 as the plurality of switches 104 having a first plurality of switches 104A, a second plurality of switches 104B, a third plurality of switches 104C, and a fourth plurality of switches 104D, it would be understood by one skilled in the field to which this disclosure pertains that the plurality of switches 104 may include more or less subsets of plurality of switches. For example, the plurality of switches 104 may include three subsets of plurality of switches or five subsets of plurality of switches. In some embodiments, each switch in the plurality of switches 104 may be associated with a switch type. Additionally, although illustrated in FIG. 1 as the first plurality of switches 104A, the second plurality of switches 104B, the third plurality of switches 104C, and the fourth plurality of switches 104D each having two switches of the plurality of switches 104, it would be understood by one skilled in the field to which this disclosure pertains that the first plurality of switches 104A, the second plurality of switches 104B, the third plurality of switches 104C, and/or the fourth plurality of switches 104D may include more switches of the plurality of switches For example, the first plurality of switches 104A may include three switches and the second plurality of switches 104B may include six switches.

In some embodiments, the system for generating a life curve associated with a switch type 100 may include a plurality of loads 106. In some embodiments, each load of the plurality of loads 106 may be associated with one of the plurality of switches 104. In this regard, for example, each switch in the plurality of switches 104 may be configured to connect and disconnect an associated load of the plurality of loads 106 from the switch testing apparatus 102. In some embodiments, the plurality of loads 106 may include resistive loads. Additionally or alternatively, the plurality of loads 106 may include inductive loads. In some embodiments, inductive loads may be associated with a power factor (pF). In some embodiments, some or all of the plurality of switches 104 may be associated with a first contact type. In some embodiments, the first contact type may be normally closed (NC). That is, some or all of the plurality of switches 104 associated with the first contact type may be configured to operate in a closed position more often than not. Additionally or alternatively, some or all of the plurality of switches 104 may be associated with a second contact type. In some embodiments, the second contact type may be normally open (NO). That is, some or all of the plurality of switches 104 may be configured to operate in an open position more often than not.

In some embodiments, the system for generating a life curve associated with a switch type 100 may include a switch testing apparatus 102. In this regard, for example, the switch testing apparatus 102 may be in electrical communication with the plurality of switches 104. In some embodiments, the switch testing apparatus 102 may be configured to generate a switch failure dataset. In some embodiments, the switch failure dataset may be associated with the switch type (e.g., the switch type associated with the plurality of switches 104). In some embodiments, the switch failure dataset may include mean failure data associated with the switch type. In some embodiments, the mean failure data may indicate a predicted number of times a switch of the switch type may be cycled before failing.

In some embodiments, the switch testing apparatus 102 may be configured to generate the switch failure dataset. In this regard, for example, the switch testing apparatus 102 may be configured to cause the first plurality of switches 104A associated with the switch type to perform one or more switch cycles. In some embodiments, in each switch cycle a first current of a plurality of currents may be applied to each switch in the first plurality of switches 104A. In some embodiments, each switch cycle may include an on time period and an off time period. In this regard, for example, the first current may be applied to each switch during the on time period. In some embodiments, the on time period may be between approximately 0.1 seconds and 2 seconds. In this regard, for example, each switch of the plurality of switches 104 may be cycled approximately 30 times per minute. In some embodiments the off time period may be equal in duration to the on time period. Alternatively, the off time period may not be equal in duration to the on time period. For example, the off time period may be longer in duration to the on time period or shorter in duration to the on time period. In some embodiments, the off time period may be between approximately 0.1 seconds and 2 seconds. In some embodiments, the first current may be between 2 amps and 4 amps (e.g., the first current may be 3 amps).

In some embodiments, the switch testing apparatus 102 may be configured to determine that each of the first plurality of switches 104A has failed. In some embodiments, determining whether each of the first plurality of switches 104A has failed may be based on a determination that each of the first plurality of switches 104A has suffered one or more faults. For example, the one or more faults may include a weld fault. In this regard, for example, a weld fault may occur when a spring component of a switch in the plurality of switches 104 becomes stuck. As another example, the one or more faults may include a current fault. In this regard, for example, a current fault may occur when a spring component of a switch in the plurality of switches 104 fails to contact a static component of the switch in the plurality of switches 104. In some embodiments, for example, the switch testing apparatus 102 may be configured to determine that each of the first plurality of switches 104A has failed when each of the first plurality of switches 104A has suffered one or more faults. For example, the switch testing apparatus 102 may be configured to determine that each of the first plurality of switches 104A has failed when each of the first plurality of switches 104A has suffered ten faults.

In some embodiments, based at least in part on determining that each of the first plurality of switches 104A has failed, the switch testing apparatus 102 may determine a number of times that each switch in the first plurality of switches 104A was cycled before failing. In this regard, for example, the switch testing apparatus 102 may determine a number of times that each switch in the first plurality of switches 104A was cycled before suffering ten faults.

In some embodiments, the switch testing apparatus 102 may be configured to generate first failure data associated with the first plurality of switches 104A. In some embodiments, the first failure data may be generated based at least on the number of switch cycles each of the first plurality of switches 104A performed before failing. For example, the first failure data may indicate that a first switch in the first plurality of switches 104A was cycled 1.35 million times before failing and that a second switch in the first plurality of switches 104A was cycled 1.6 million times before failing.

In some embodiments, the switch testing apparatus 102 may be configured to iteratively generate other failure data based at least on applying other currents of the plurality of currents to other pluralities of switches in the plurality of switches associated with the switch type (e.g., the switch testing apparatus 102 may be configured to iteratively generate the other failure data similarly to how the switch testing apparatus 102 is configured to generate the first failure data). For example, the switch testing apparatus 102 may generate other failure data associated with the second plurality of switches 104B by applying a second current of the plurality of currents to the second plurality of switches 104B. In some embodiments, the second current may be between 6 amps and 8 amps (e.g., the second current may be 7 amps). As another example, the switch testing apparatus 102 may generate other failure data associated with the third plurality of switches 104C by applying a third current of the plurality of currents to the third plurality of switches 104C. In some embodiments, the third current may be between 11 amps and 13 amps (e.g., the third current may be 12 amps). As another example, the switch testing apparatus 102 may generate other failure data associated with the second plurality of switches 104D by applying a fourth current of the plurality of currents to the fourth plurality of switches 104D. In some embodiments, the fourth current may be between 15 amps and 17 amps (e.g., the fourth current may be 16 amps).

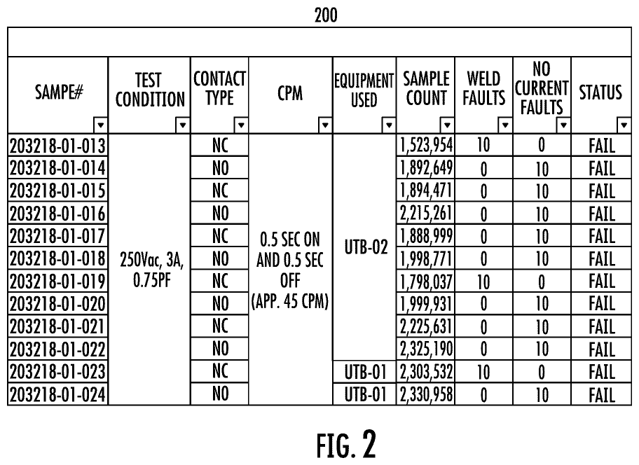

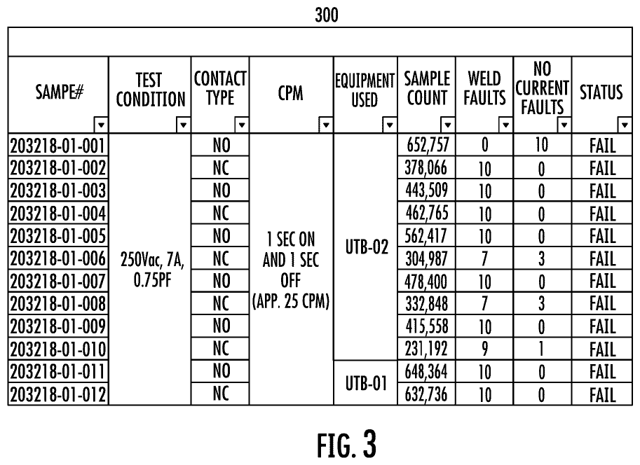

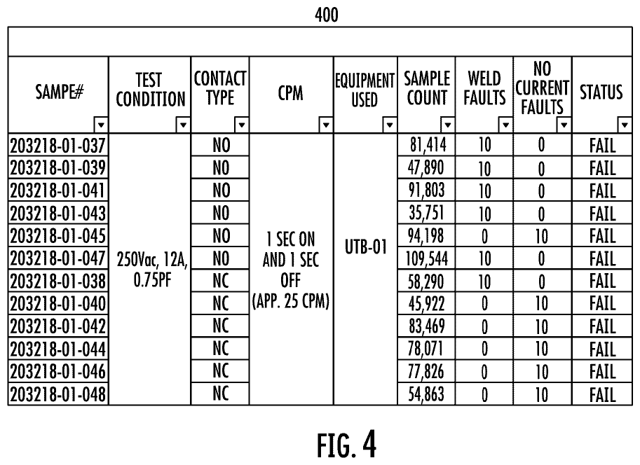

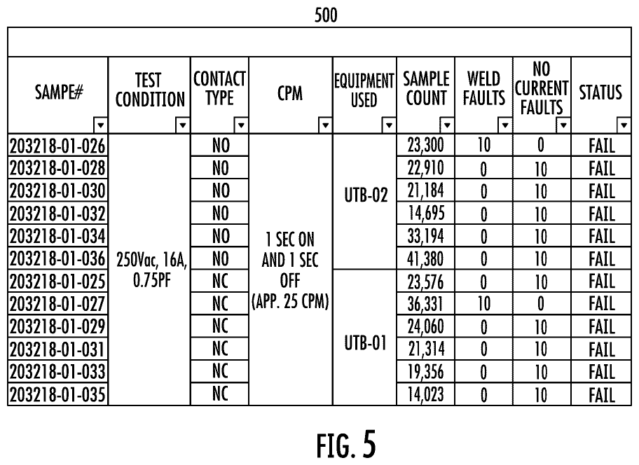

In some embodiments, the switch testing apparatus 102 may be configured to automatically output the first failure data to a first failure data interface 200, such as the first failure data interface 200 illustrated in FIG. 2. In some embodiments, the switch testing apparatus 102 may be configured to automatically output the other failure data associated with the second plurality of switches 104B to a first other failure data interface 300, such as the first other failure data interface 300 illustrated in FIG. 3. In some embodiments, the switch testing apparatus 102 may be configured to automatically output the other failure data associated with the third plurality of switches 104C to a second other failure data interface 400, such as the second other failure data interface 400 illustrated in FIG. 4. In some embodiments, the switch testing apparatus 102 may be configured to automatically output the other failure data associated with the fourth plurality of switches 104D to a third other failure data interface 500, such as the third other failure data interface 500 illustrated in FIG. 5.

In some embodiments, the switch testing apparatus 102 may be configured to automatically output test conditions associated with the first plurality of switches 104A to the first failure data interface 200 (e.g., a power factor (pf) associated with one or more of the plurality of loads 106 associated with the first plurality of switches 104A). In some embodiments, the switch testing apparatus 102 may be configured to automatically output test conditions associated with the second plurality of switches 104B to the first other failure data interface 300. In some embodiments, the switch testing apparatus 102 may be configured to automatically output test conditions associated with the third plurality of switches 104C to the second other failure data interface 400. In some embodiments, the switch testing apparatus 102 may be configured to automatically output test conditions associated with the fourth plurality of switches 104C to the third other failure data interface 500.

In some embodiments, the switch testing apparatus 102 may be configured to automatically output whether each switch in the first plurality of switches 104A is associated with the first contact type (e.g., contact type NC) or the second contact type (e.g., contact type NO) to the first failure data interface 200. In some embodiments, the switch testing apparatus 102 may be configured to automatically output whether each switch in the second plurality of switches 104B is associated with the first contact type (e.g., contact type NC) or the second contact type (e.g., contact type NO) to the first other failure data interface 300. In some embodiments, the switch testing apparatus 102 may be configured to automatically output whether each switch in the third plurality of switches 104C is associated with the first contact type (e.g., contact type NC) or the second contact type (e.g., contact type NO) to the second other failure data interface 400. In some embodiments, the switch testing apparatus 102 may be configured to automatically output whether each switch in the fourth plurality of switches 104D is associated with the first contact type (e.g., contact type NC) or the second contact type (e.g., contact type NO) to the third other failure data interface 500.

In some embodiments, the switch testing apparatus 102 may be configured to automatically output how many weld faults each switch in the first plurality of switches 104A has suffered to the first failure data interface 200. In some embodiments, the switch testing apparatus 102 may be configured to automatically output how many weld faults each switch in the second plurality of switches 104B has suffered to the first other failure data interface 300. In some embodiments, the switch testing apparatus 102 may be configured to automatically output how many weld faults each switch in the third plurality of switches 104C has suffered to the second other failure data interface 400. In some embodiments, the switch testing apparatus 102 may be configured to automatically output how many weld faults each switch in the fourth plurality of switches 104D has suffered to the third other failure data interface 500.

In some embodiments, the switch testing apparatus 102 may be configured to automatically output how many current faults each switch in the first plurality of switches 104A has suffered to the first failure data interface 200. In some embodiments, the switch testing apparatus 102 may be configured to automatically output how many current faults each switch in the second plurality of switches 104B has suffered to the first other failure data interface 300. In some embodiments, the switch testing apparatus 102 may be configured to automatically output how many current faults each switch in the third plurality of switches 104C has suffered to the second other failure data interface 400. In some embodiments, the switch testing apparatus 102 may be configured to automatically output how many current faults each switch in the fourth plurality of switches 104D has suffered to the third other failure data interface 500.

In some embodiments, the switch testing apparatus 102 may be configured to generate preliminary mean failure data associated with the switch type at least based on the first failure data and the other failure data. In this regard, for example, the preliminary mean failure data may indicate an average number of times that a switch associated with the switch type may be cycled before failing. In some embodiments, the mean failure data may indicate an average number of times that a switch associated with the switch type may be cycled before failing at each of the plurality of currents applied to the plurality of switches 104. For example, the preliminary mean failure data may indicate an average number of times that the first plurality of switches 104A were cycled before failing, an average number of times that the second plurality of switches 104B were cycled before failing, an average number of times that the third plurality of switches 104C were cycled before failing, and an average number of times that the fourth plurality of switches 104D were cycled before failing.

In some embodiments, the switch testing apparatus 102 may be configured to generate the mean failure data by adjusting the preliminary mean failure data by a confidence level. In this regard, for example, the mean failure data may indicate a predicted number of times that a switch associated with the switch type may be cycled before failing. In some embodiments, the mean failure data may indicate a predicted number of times that a switch associated with the switch type may be cycled before failing at each of the plurality of currents applied to the plurality of switches 104. For example, the mean failure data may indicate a predicted number of times that the first plurality of switches 104A may be cycled performed before failing, a predicted number of times that the second plurality of switches 104B may be cycled performed before failing, a predicted number of times that the third plurality of switches 104C may be cycled performed before failing, and a predicted number of times that the fourth plurality of switches 104D may be cycled performed before failing.

In some embodiments, the confidence level may indicate, that if the switch testing apparatus 102 generated the preliminary mean failure data associated with the switch type again, a likelihood that the average number of times that a switch associated with the switch type may be cycled before failing is greater than the predicted number of times that a switch associated with the switch type may be cycled before failing. For example, if the confidence level is equal to 90 percent, the confidence level would indicate, that if the switch testing apparatus 102 generated the preliminary mean failure data associated with the switch type again, there is a 90 percent chance that the average number of times that a switch associated with the switch type may be cycled before failing is greater than the predicted number of times that a switch associated with the switch type may be cycled before failing.

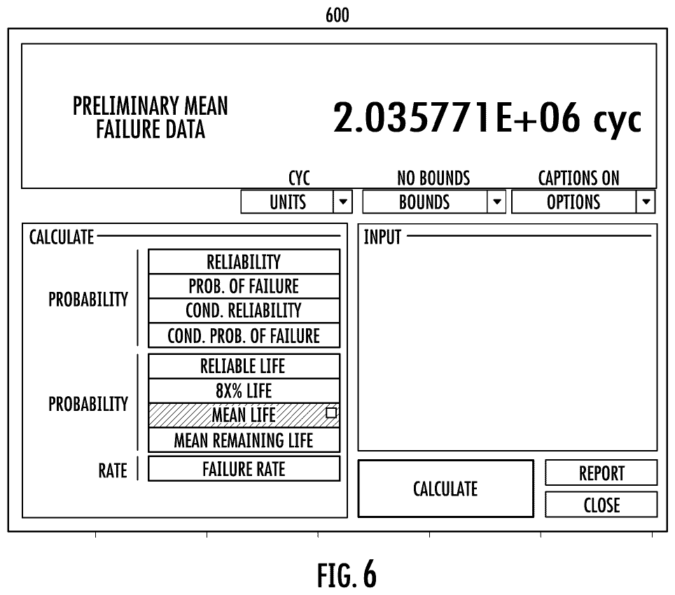

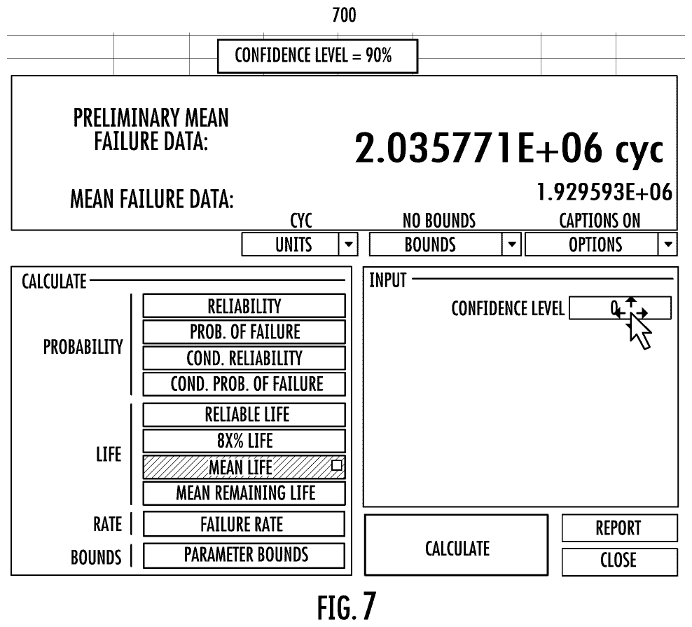

In some embodiments, the switch testing apparatus 102 may be configured to automatically display at least some of the preliminary mean failure data on a first mean failure data interface 600. For example, the first mean failure data interface 600 illustrated in FIG. 6 displays preliminary mean failure data associated with the first plurality of switches 104A. In some embodiments, the switch testing apparatus 102 may be configured to automatically display at least some of the mean failure data on a second mean failure data interface 700. For example, the second mean failure data interface 700 illustrated in FIG. 7 displays preliminary mean failure data associated with the first plurality of switches 104A.

In some embodiments, the switch testing apparatus 102 may be configured to determine a best fit distribution for the switch type based at least on the switch failure dataset using one or more regression models. In some embodiments, the best fit distribution may be selected from a plurality of best fit distributions. In this regard, for example, the plurality of best fit distributions may include an exponential distribution, a logarithmic distribution, a linear distribution, or a power distribution. In some embodiments, each of the plurality of best fit distributions may be associated with a R² value (e.g., a goodness-of-fit value). In some embodiments, the selected best fit distribution may be the best fit distribution that has the highest R² value. For example, if the linear distribution is associated with a R² value of 0.945, the exponential distribution is associated with a R² value of 0.964, the logarithmic distribution is associated with a R² value of 0.936, and the power distribution has a R² value of 0.954, the exponential distribution would be the selected best fit distribution.

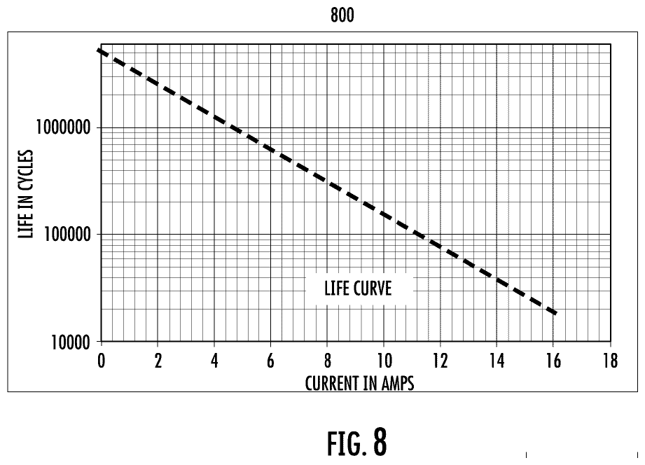

In some embodiments, the switch testing apparatus 102 may be configured to generate a live curve for the switch type based at least on the best fit distribution. In this regard, the life curve may indicate an excepted number of cycles that a switch of the switch type may be cycled at one or more currents before failing (e.g., the life of a switch of the switch type). In some embodiments, the switch testing apparatus 102 may be configured to automatically display the life curve for the switch type on a live curve interface 800, such as the live curve interface 800 illustrated in FIG. 8. For example, the live curve interface 800 shown in FIG. 8 illustrates a life curve for the switch type that was generated based on an exponential distribution.

### Example Methods

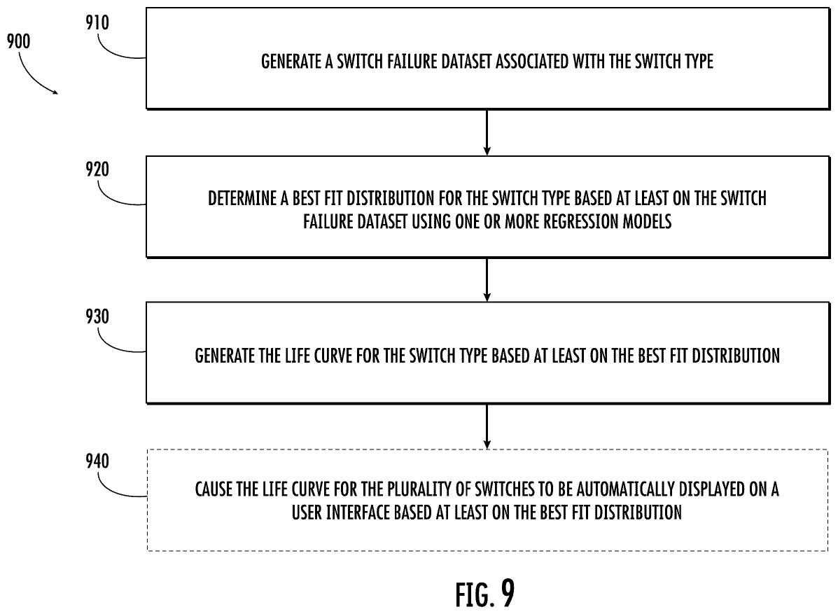

Referring now to FIG. 9, a flowchart providing an example method 900 for generating a life curve associated with a switch type is illustrated. In this regard, FIG. 9 illustrates operations that may be performed by the switch testing apparatus 102.

As shown in block 910, the method 900 for generating a life curve associated with a switch type may include generating a switch failure dataset associated with the switch type. As described above, in some embodiments, the switch failure dataset may be associated with the switch type (e.g., the switch type associated with the plurality of switches). In some embodiments, the switch failure dataset may include mean failure data associated with the switch type. In some embodiments, the mean failure data may indicate a predicted number of times a switch of the switch type may be cycled before failing.

As described above, in some embodiments, generating the switch failure dataset associated with the switch type may include causing the first plurality of switches associated with the switch type to perform one or more switch cycles. In some embodiments, in each switch cycle a first current of a plurality of currents may be applied to each switch in the first plurality of switches. In some embodiments, each switch cycle may include an on time period and an off time period. In this regard, for example, the first current may be applied to each switch during the on time period. In some embodiments, the on time period may be between approximately 0.1 seconds and 2 seconds. In some embodiments the off time period may be equal in duration to the on time period. Alternatively, the off time period may not be equal in duration to the on time period. For example, the off time period may be longer in duration to the on time period or shorter in duration to the on time period. In some embodiments, the off time period may be between approximately 0.1 seconds and 2 seconds. In some embodiments, the first current may be between 2 amps and 4 amps (e.g., the first current may be 3 amps).

As described above, in some embodiments, generating the switch failure dataset associated with the switch type may include determining that each of the first plurality of switches has failed. In some embodiments, determining whether each of the first plurality of switches has failed may be based on a determination that each of the first plurality of switches has suffered one or more faults. For example, the one or more faults may include a weld fault. In this regard, for example, a weld fault may occur when a spring component of a switch in the plurality of switches becomes stuck. As another example, the one or more faults may include a current fault. In this regard, for example, a current fault may occur when a spring component of a switch in the plurality of switches fails to contact a static component of the switch in the plurality of switches. In some embodiments, for example, each of the first plurality of switches has failed when each of the first plurality of switches has suffered a number of faults. For example, each of the first plurality of switches has failed when each of the first plurality of switches has suffered ten faults.

In some embodiments, based at least in part on determining that each of the first plurality of switches has failed, generating the switch failure dataset associated with the switch type may include determining a number of times that each switch in the first plurality of switches was cycled before failing.

As described above, in some embodiments, generating the switch failure dataset associated with the switch type may include first failure data associated with the first plurality of switches. In some embodiments, the first failure data may be generated based at least on the number of switch cycles each of the first plurality of switches performed before failing. For example, the first failure data may indicate that a first switch in the first plurality of switches was cycled 1.35 million times before failing and that a second switch in the first plurality of switches was cycled 1.6 million times before failing.

As described above, in some embodiments, generating the switch failure dataset associated with the switch type may include iteratively generating other failure data based at least on applying other currents of the plurality of currents to other pluralities of switches in the plurality of switches associated with the switch type (e.g., iteratively generating the other failure data similarly to how the first failure data is generated). For example, other failure data associated with the second plurality of switches may be generated by applying a second current of the plurality of currents to the second plurality of switches. In some embodiments, the second current may be between 6 amps and 8 amps (e.g., the second current may be 7 amps). As another example, other failure data associated with the third plurality of switches may be generated by applying a third current of the plurality of currents to the third plurality of switches. In some embodiments, the third current may be between 11 amps and 13 amps (e.g., the third current may be 12 amps). As another example, other failure data associated with the second plurality of switches may be generated by applying a fourth current of the plurality of currents to the fourth plurality of switches. In some embodiments, the fourth current may be between 15 amps and 17 amps (e.g., the fourth current may be 16 amps).

As described above, in some embodiments, generating the switch failure dataset associated with the switch type may include generating preliminary mean failure data associated with the switch type at least based on the first failure data and the other failure data. In this regard, for example, the preliminary mean failure data may indicate an average number of times that a switch associated with the switch type may be cycled before failing. In some embodiments, the mean failure data may indicate an average number of times that a switch associated with the switch type may be cycled before failing at each of the plurality of currents applied to the plurality of switches. For example, the preliminary mean failure data may indicate an average number of times that the first plurality of switches were cycled before failing, an average number of times that the second plurality of switches were cycled before failing, an average number of times that the third plurality of switches were cycled before failing, and an average number of times that the fourth plurality of switches were cycled before failing.

As described above, in some embodiments, generating the switch failure dataset associated with the switch type may include generating the mean failure data by adjusting the preliminary mean failure data by a confidence level. In this regard, for example, the mean failure data may indicate a predicted number of times that a switch associated with the switch type may be cycled before failing. In some embodiments, the mean failure data may indicate a predicted number of times that a switch associated with the switch type may be cycled before failing at each of the plurality of currents applied to the plurality of switches. For example, the mean failure data may indicate a predicted number of times that the first plurality of switches may be cycled performed before failing, a predicted number of times that the second plurality of switches may be cycled performed before failing, a predicted number of times that the third plurality of switches may be cycled performed before failing, and a predicted number of times that the fourth plurality of switches may be cycled performed before failing.

As described above, in some embodiments, the confidence level may indicate, that if the preliminary mean failure data associated with the switch type is generated again, a likelihood that the average number of times that a switch associated with the switch type may be cycled before failing is greater than the predicted number of times that a switch associated with the switch type may be cycled before failing. For example, if the confidence level is equal to 90 percent, the confidence level would indicate, that if the preliminary mean failure data associated with the switch type is generated again, there is a 90 percent chance that the average number of times that a switch associated with the switch type may be cycled before failing is greater than the predicted number of times that a switch associated with the switch type may be cycled before failing.

As shown in block 920, the method 900 for generating a life curve associated with a switch type may include determining a best fit distribution for the switch type based at least on the switch failure dataset using one or more regression models. As described above, in some embodiments, the best fit distribution may be selected from a plurality of best fit distributions. In this regard, for example, the plurality of best fit distributions may include an exponential distribution, a logarithmic distribution, a linear distribution, or a power distribution. In some embodiments, each of the plurality of best fit distributions may be associated with a R² value (e.g., a goodness-of-fit value). In some embodiments, the selected best fit distribution may be the best fit distribution that has the highest R² value. For example, if the linear distribution is associated with a R² value of 0.945, the exponential distribution is associated with a R² value of 0.964, the logarithmic distribution is associated with a R² value of 0.936, and the power distribution has a R² value of 0.954, the exponential distribution would be the selected best fit distribution.

As shown in block 930, the method 900 for generating a life curve associated with a switch type may include generating the life curve for the switch type based at least on the best fit distribution. As described above, in some embodiments, generating the life curve may indicate an excepted number of cycles that a switch of the switch type may be cycled at one or more currents before failing (e.g., the life of a switch of the switch type).

As shown in block 940, the method 900 for generating a life curve associated with a switch type may optionally include causing the life curve for the plurality of switches to be automatically displayed on a user interface based at least on the best fit distribution.

### Example Computer Processing Device

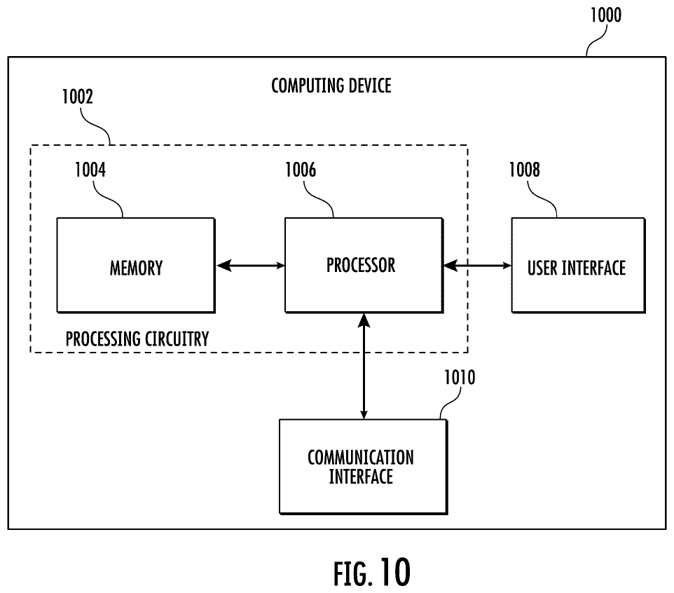

With reference to FIG. 10, a block diagram of an example computer processing device 1000 is illustrated in accordance with some example embodiments. In some embodiments, the switch testing apparatus 102 and/or other devices may be embodied as one or more computer processing devices, such as the computer processing device 1000 in FIG. 10. However, it should be noted that the components, devices, or elements illustrated in and described with respect to FIG. 10 below may not be mandatory and thus one or more may be omitted in certain embodiments. Additionally, some embodiments may include further or different components, devices or elements beyond those illustrated in and described with respect to FIG. 10.

The computer processing device 1000 may include or otherwise be in communication with processing circuitry 1002 that is configurable to perform actions in accordance with one or more embodiments disclosed herein. In this regard, the processing circuitry 1002 may be configured to perform and/or control performance of one or more functionalities of the computer processing device 1000 in accordance with various embodiments, and thus may provide means for performing functionalities of the computer processing device 1000 in accordance with various embodiments. The processing circuitry 1002 may be configured to perform data processing, application execution and/or other processing and management services according to one or more embodiments. In some embodiments, the computer processing device 1000 or a portion(s) or component(s) thereof, such as the processing circuitry 1002, may be embodied as or comprise a chip or chip set. In other words, the computer processing device 1000 or the processing circuitry 1002 may comprise one or more physical packages (e.g., chips) including materials, components and/or wires on a structural assembly (e.g., a baseboard). The structural assembly may provide physical strength, conservation of size, and/or limitation of electrical interaction for component circuitry included thereon. The computer processing device 1000 or the processing circuitry 1002 may therefore, in some cases, be configured to implement an embodiment of the disclosure on a single chip or as a single “system on a chip.” As such, in some cases, a chip or chipset may constitute means for performing one or more operations for providing the functionalities described herein.

In some embodiments, the processing circuitry 1002 may include a processor 1006 and, in some embodiments, such as that illustrated in FIG. 10, may further include memory 1004. The processing circuitry 1002 may be in communication with or otherwise control a user interface 1008 and/or a communication interface 1010. As such, the processing circuitry 1002 may be embodied as a circuit chip (e.g., an integrated circuit chip) configured (e.g., with hardware, software or a combination of hardware and software) to perform operations described herein.

The processor 1006 may be embodied in a number of different ways. For example, the processor 1006 may be embodied as various processing means such as one or more of a microprocessor or other processing element, a coprocessor, a controller or various other computing or processing devices including integrated circuits such as, for example, an ASIC (application specific integrated circuit), an FPGA (field programmable gate array), or the like. Although illustrated as a single processor, it will be appreciated that the processor 1006 may comprise a plurality of processors. The plurality of processors may be in operative communication with each other and may be collectively configured to perform one or more functionalities of the computer processing device 1000 as described herein. In some embodiments, the processor 1006 may be configured to execute instructions stored in the memory 1004 or otherwise accessible to the processor 1006. As such, whether configured by hardware or by a combination of hardware and software, the processor 1006 may represent an entity (e.g., physically embodied in circuitry-in the form of processing circuitry 1002) capable of performing operations according to embodiments of the present disclosure while configured accordingly. Thus, for example, when the processor 1006 is embodied as an ASIC, FPGA or the like, the processor 1006 may be specifically configured hardware for conducting the operations described herein. Alternatively, as another example, when the processor 1006 is embodied as an executor of software instructions, the instructions may specifically configure the processor 1006 to perform one or more operations described herein.

In some embodiments, the memory 1004 may include one or more non-transitory memory devices such as, for example, volatile and/or non-volatile memory that may be either fixed or removable. In this regard, the memory 1004 may comprise a non-transitory computer-readable storage medium. It will be appreciated that while the memory 1004 is illustrated as a single memory, the memory 1004 may comprise a plurality of memories. The memory 1004 may be configured to store information, data, applications, instructions and/or the like for enabling the computer processing device 1000 to carry out various functions in accordance with one or more embodiments. For example, the memory 1004 may be configured to buffer input data for processing by the processor 1006. Additionally or alternatively, the memory 1004 may be configured to store instructions for execution by the processor 1006. As yet another alternative, the memory 1004 may include one or more databases that may store a variety of files, contents or data sets. Among the contents of the memory 1004, applications may be stored for execution by the processor 1006 in order to carry out the functionality associated with each respective application. In some cases, the memory 1004 may be in communication with one or more of the processor 1006, user interface 1008, and/or communication interface 1010 via a bus(es) for passing information among components of the computer processing device 1000.

The user interface 1008 may be in communication with the processing circuitry 1002 to receive an indication of a user input at the user interface 1008 and/or to provide an audible, visual, mechanical or other output to the user. As such, the user interface 1008 may include, for example, a keyboard, a mouse, a joystick, a display, a touch screen display, a microphone, a speaker, and/or other input/output mechanisms. As such, the user interface 1008 may, in some embodiments, provide means for a user to access and interact with the switch testing apparatus 102 and/or other devices.

The communication interface 1010 may include one or more interface mechanisms for enabling communication with other devices and/or networks. In some cases, the communication interface 1010 may be any means such as a device or circuitry embodied in either hardware, or a combination of hardware and software that is configured to receive and/or transmit data from/to a network and/or any other device or module in communication with the processing circuitry 1002. By way of example, the communication interface 1010 may be configured to enable the switch testing apparatus 102 to communicate with the plurality of switches 104 and/or other devices. Accordingly, the communication interface 1010 may, for example, include an antenna (or multiple antennas) and supporting hardware and/or software for enabling communications with a wireless communication network (e.g., a wireless local area network, cellular network, global positing system network, and/or the like) and/or a communication modem or other hardware/software for supporting communication via cable, digital subscriber line (DSL), universal serial bus (USB), Ethernet or other methods.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the invention(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

That which is claimed:

1. A method of generating a life curve associated with a switch type, the method comprising:
generating a switch failure dataset associated with the switch type, wherein the switch failure dataset comprises mean failure data associated with the switch type indicating a predicted number of times a switch of the switch type may be cycled before failing;
determining a best fit distribution for the switch type based at least on the switch failure dataset using one or more regression models; and
generating the life curve for the switch type based at least on the best fit distribution.

2. The method of claim 1, wherein generating the switch failure dataset comprises:
causing a first plurality of switches associated with the switch type to perform one or more switch cycles, wherein in each switch cycle a first current of a plurality of currents is applied to each switch of the first plurality of switches;
determining that each of the first plurality of switches has failed;
determining a number of switch cycles each of the first plurality of switches performed before failing;
generating first failure data associated with the first plurality of switches based at least on the number of switch cycles each of the first plurality of switches performed before failing;
iteratively generating other failure data based at least on applying other currents of the plurality of currents to other pluralities of switches associated with the switch type;
generating preliminary mean failure data associated with the switch type based at least on the first failure data and the other failure data; and
generating the mean failure data by adjusting the preliminary mean failure data by a confidence level.

3. The method of claim 2, wherein each of the one or more switch cycles comprises an on time period and an off time period.

4. The method of claim 3, wherein the first current is applied to each switch of the first plurality of switches during the on time period.

5. The method of claim 3, wherein the first current is between one ampere and twenty amperes.

6. The method of claim 2, wherein the on period is less than two seconds.

7. The method of claim 3, wherein a switch of the first plurality of switches has failed when the switch is unable to be cycled between the on time period and the off time period.

8. The method of claim 1, wherein the best fit distribution is selected from a plurality of best fit distributions.

9. The method of claim 8, wherein the plurality of best fit distributions comprise an exponential distribution, a logarithmic distribution, a linear distribution, and a power distribution.

10. The method of claim 1, further comprising:
causing the life curve for the switch type to be automatically displayed on a user interface based at least on the best fit distribution.

11. A system for generating a life curve associated with a switch type, the system comprising:
a plurality of switches associated with the switch type; and
a switch testing apparatus comprising at least one processor and at least one non-transitory memory having one or more programs stored thereon that include instructions that, when executed by the at least one processor, causes the switch testing apparatus to:
generate a switch failure dataset associated with the switch type, wherein the switch failure dataset comprises mean failure data associated with the switch type indicating a predicted number of times a switch of the switch type may be cycled before failing;
determine a best fit distribution for the switch type based at least on the switch failure dataset using one or more regression models; and
generate the life curve for the switch type based at least on the best fit distribution.

12. The system of claim 11, wherein the switch testing apparatus is caused to generate the switch failure dataset by:
causing a first plurality of switches of the plurality of switches associated with the switch type to perform one or more switch cycles, wherein in each switch cycle a first current of a plurality of currents is applied to each switch of the first plurality of switches;
determining that each of the first plurality of switches has failed;
determining a number of switch cycles each of the first plurality of switches performed before failing;
generating first failure data associated with the first plurality of switches based at least on the number of switch cycles each of the first plurality of switches performed before failing;
iteratively generating other failure data based on applying other currents of the plurality of currents to other pluralities of switches of the plurality of switches associated with the switch type;
generating preliminary mean failure data associated with the switch type based at least on the first failure data and the other failure data; and
generating the mean failure data by adjusting the preliminary mean failure data by a confidence level.

13. The system of claim 12, wherein each of the one or more switch cycles comprises an on time period and an off time period.

14. The system of claim 13, wherein the first current is applied to each switch of the first plurality of switches during the on time period.

15. The system of claim 13, wherein the first current is between one ampere and twenty amperes.

16. The system of claim 12, wherein the on period is less than two seconds.

17. The system of claim 13, wherein a switch of the first plurality of switches has failed when the switch is unable to be cycled between the on time period and the off time period.

18. The system of claim 11, wherein the best fit distribution is selected from a plurality of best fit distributions, wherein of best fit distributions comprise an exponential distribution, a logarithmic distribution, a linear distribution, and a power distribution.

19. The system of claim 11, wherein the switch testing apparatus is further caused to:
automatically display the life curve for the switch type on a user interface based at least on the best fit distribution.

20. At least one non-transitory computer-readable storage medium for generating a life curve associated with a switch type, the at least one non-transitory computer-readable storage medium having computer-executable program code portions stored therein, the computer-executable program code portions comprising program code instructions configured to:
generate a switch failure dataset associated with the switch type, wherein the switch failure dataset comprises mean failure data associated with the switch type indicating a predicted number of times a switch of the switch type may be cycled before failing;
determine a best fit distribution for the switch type based at least on the switch failure dataset using one or more regression models; and
generate the life curve for the switch type based at least on the best fit distribution.
